(19) United States
(12) Patent Application Publication
(10) Pub. No.: US 2008/0151492 A1
(43) Pub. Date: Jun. 26, 2008

(54) Computer case with intake filter with positive airflow

(76) Inventor: Charles W. Maddox, Santa Ana, CA (US)

Correspondence Address: STETINA BRUNDA GARRED & BRUCKER, 75 ENTERPRISE, SUITE 250, ALISO VIEJO, CA, 92656, US

(21) Appl. No.: 12/004,267

(22) Filed: Dec. 20, 2007

Related U.S. Application Data
(60) Provisional application No. 60/871,934, filed on Dec. 26, 2006.

(51) Int. Cl. H05K 7/20

(52) U.S. Cl. 361/687

(57) ABSTRACT

There is provided a computer case including an enclosure having a forward face and a rearward face. An inlet opening is formed on the forward face and is configured to allow ambient air to enter the enclosure through the inlet opening. At least one outlet opening is formed on the rearward face and is configured to allow air within the enclosure to exit through the outlet opening at a first flow rate. The inlet opening and the outlet opening are in fluid communication with each other to define airflow from the forward face to the rearward face within the enclosure. The computer case further includes an inlet assembly in fluid communication with the inlet opening. The inlet assembly includes an air filter and a fan. The fan directs air through the filter and into the inlet opening at a second flow rate being greater than the first flow rate.

### CROSS-REFERENCE TO RELATED APPLICATIONS

The present application claims priority to Provisional Application No. 60871934 filed on Dec. 26, 2006 entitled Filtered, Pressurized Computer Case for Personal Computers and Servers, the entire contents of which are incorporated herein by reference.

### STATEMENT RE: FEDERALLY SPONSORED RESEARCH/DEVELOPMENT

(Not Applicable)

### BACKGROUND OF THE INVENTION

1. Field of the Invention

The present invention relates generally to computer component protection and more particularly, to a computer case having a positive air pressure to substantially inhibit the introduction of foreign particles into the case and to create an airflow that facilitates cooling of computer components.

2. Description of the Related Art

Computers include many delicate components which may only operate within a specific temperature range. If the temperature of a particular component exceeds its maximum operating temperature, the component may become damaged. Some components are programmed to shut down as the temperature approaches its maximum temperature. In either case, computer operation is likely interrupted, which may result in the loss of data and downtime to the user.

Therefore, a great deal of attention is devoted to designing a system for maintaining the temperature of the components within their prescribed operating temperature range. Many computer cases commonly employ a system which creates airflow through the case. In general, cool ambient air is drawn into the computer case, and warm air exits the computer case. The components are positioned within the computer case and placed within the airflow. As the cooler air travels over the hotter component, heat is transferred from the component to the air. In this regard, the component may operate within its operable temperature range for longer periods of time.

However, the ambient air drawn into the computer case includes dust and foreign particles which may mitigate the cooling of the computer components. In particular, as the air travels through the computer case, the dust or foreign particles are attracted to the computer components by the electromagnetic field they generate. When the air passes over the component, the dust or foreign particles push the airflow away from the component, thereby creating turbulent airflow. Consequently, the cooler air may not be brought into contact with the component. Therefore, the component is less likely to transfer heat to the passing air.

Although component damage caused by dust and foreign particles may occur anywhere, such damage may be particularly prevalent in environments with high concentrations of dust and foreign particles. Exemplary environments may include wood-working and metal-working shops where shavings of wood and metal are present in the air Consequently, additional measures may be taken in such environments to shield the computer components from the airborne particles.

One particular design aimed at insulating the computer case from dust and foreign particles is disclosed in U.S. Design Pat. No. D445,420 (referred to herein as the '420 patent). The '420 patent discloses a housing sized and configured to fit around a computer case. The housing is intended to be used in connection with a fan and filter. A fan directs air through the filter and into the housing. The filter substantially removes the dust and foreign particles from the air passing into the housing. As such, all of the air entering the housing is filtered air. Therefore, dust and foreign objects are less likely to settle on the components and cause them to overheat.

While the '420 patent may provide cleaner air to the components, the housing completely covers the computer case. Therefore, access to the computer is restricted. For instance, in order to access the drive bays a hinged door must be opened. When the hinge door opens, ambient air, including dust and foreign particles may be allowed to enter the housing.

As is apparent from the foregoing, there exists a need in the art for a device which is configured to inhibit the introduction of dust and foreign particles into the computer case while at the same time creating a sufficient air flow to cool the computer components while providing access to the computer. The present invention addresses this particular need, as will be discussed in more detail below.

### BRIEF SUMMARY OF THE INVENTION

According to an aspect of the present invention, there is provided a computer case configured to inhibit the introduction of airborne particles into the computer case. The computer case includes an enclosure for housing computer components. The enclosure includes a forward face and a rearward face. An inlet opening configured to allow ambient air to enter the enclosure through the inlet opening is formed on the forward face. The enclosure further includes at least one outlet opening formed on the rearward face. The outlet opening is configured to allow air within the enclosure to exit through the outlet opening at a first flow rate. The inlet opening and the outlet opening are in fluid communication with each other to define airflow within the enclosure from the forward face to the rearward face. The computer case further includes an inlet assembly in fluid communication with the inlet opening. The inlet assembly includes an air filter and a fan. The fan directs air through the filter and into the inlet opening at a second flow rate. The second flow rate is greater than the first flow rate.

It is contemplated that the computer case mitigates the introduction of airborne particles into the enclosure by creating a positive air pressure within the enclosure. The positive air pressure is a result of the second flow rate being greater than the first flow rate. In other words, more air is being introduced into the enclosure through the inlet opening than is leaving the enclosure through the outlet opening. Furthermore, air directed into the enclosure passes through a filter, thereby purifying the air. The computer case may also create airflow flowing from the forward face to the rearward face, which is similar to airflow within a typical computer case. Consequently, air flows over the computer components in a manner similar to many existing computer cases.

According to another aspect of the present invention, there is provided a modular computer airflow generator configured to inhibit the introduction of airborne particles into a computer enclosure having inlet and outlet openings. The inlet opening is configured to allow air to enter the enclosure and the outlet opening is configured to allow air to exit the enclosure at a first flow rate.

The modular computer airflow generator includes a base and an inlet assembly connected to the base. The inlet assembly is positionable in fluid communication with the inlet opening. The inlet assembly includes an air filter and a fan. The fan directs air through the filter and into the inlet opening at a second flow rate. The second flow rate is greater than the first flow rate. The modular computer airflow generator further includes a seal connected to the base. The seal is positionable about the computer case inlet opening to fluidly seal the inlet assembly to the computer case.

It is contemplated that the modular computer airflow generator is positionable in fluid communication with the inlet assembly of an existing computer case to inhibit the introduction of airborne particles into the case. In this regard, the modular computer airflow generator may be used in connection with various computer cases. Therefore, if an existing computer case does not have sufficient airflow and filtering systems, the modular computer airflow generator may be employed to facilitate the airflow and to mitigate the introduction of airborne particles into the enclosure.

The present invention is best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings in which like numbers refer to like parts throughout and in which:

FIG. 1 is a top perspective view of a computer case configured to inhibit the introduction of airborne particles, wherein a portion of the computer case has been removed to illustrate airflow through the computer case from a forward face to a rearward face;

FIG. 2 is an enlarged sectional view of an inlet assembly in fluid communication with an inlet opening formed on the forward face of the computer case illustrated in FIG. 1, wherein the inlet assembly includes a fan, shown in phantom, and a filter;

FIG. 3 is a side sectional view of the computer case illustrated in FIG. 1, wherein the fan directs air through the filter and into the computer case, the air flowing from the forward face to the rearward face; and

FIG. 4 is a side sectional view of a modular computer airflow generator positioned adjacent to and in fluid communication with an inlet opening disposed on a forward face of a computer case.

### DETAILED DESCRIPTION OF THE INVENTION

It is well known that computer components generate heat as they operate. Each component is generally operable within a specific temperature range. Therefore, most prior art computer cases include a cooling system aimed at maintaining the temperature of the components within their operable temperature range. Many cooling systems create airflow flowing directly over the computer components. Cool ambient air is drawn into the computer while hot air is blown out of the computer. As the cool air flows over the components, heat from the components is transferred to the passing air. In general, air flows in one side, and out an opposing side. As such, the airflow in most computer cases typically flows from an inlet vent disposed on a front panel of the computer case to an outlet vent disposed on the back panel. The outlet vent is typically positioned on the back panel to prevent warm air from blowing onto the person operating the computer. An exhaust fan is normally positioned adjacent the outlet vent to blow the warm air out of the computer case.

Although drawing cooler ambient air into the computer case creates airflow which may temporarily maintain the temperature of the computer components within an operable temperature range, the ambient air likely includes airborne particles which may ultimately increase the temperature of the components. Such airborne particles may include dust, wood shavings, metal shavings, or other debris suspended in the air. As the ambient air flows over the components, the airborne particles may land on the components. The airborne particles tend to create a turbulent airflow over the components, which reduces the effectiveness of heat transfer from the component to the air. Furthermore, the airborne particles may buildup on the components and act as a thermal insulator, thereby preventing heat from leaving the component. Therefore, it is desirable to prevent airborne particles from being introduced into the computer case, while at the same time maintaining airflow through the case.

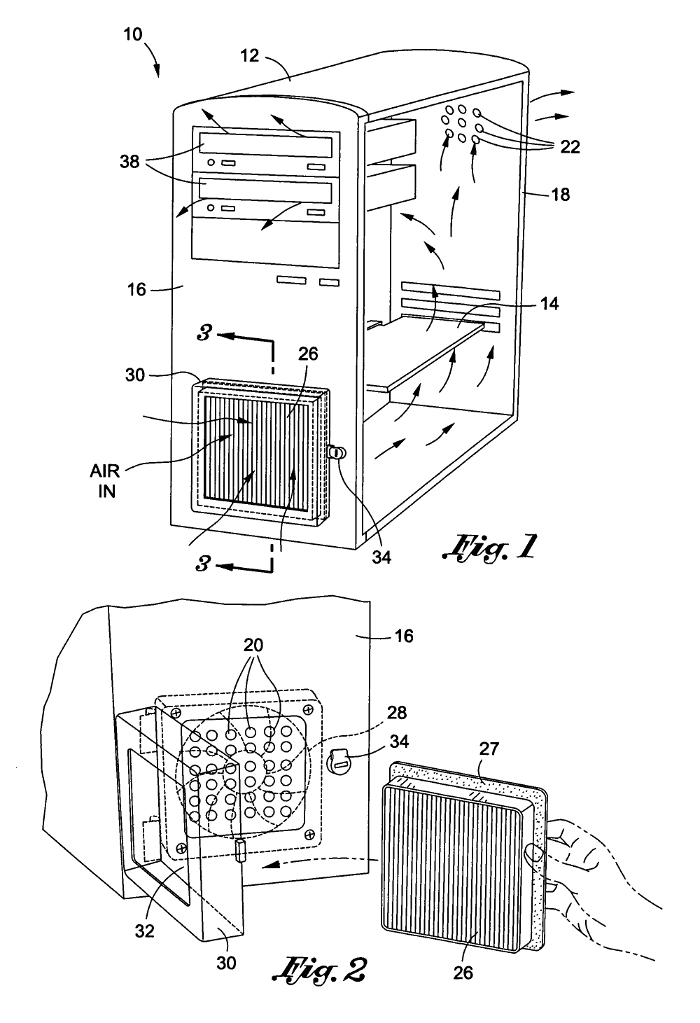

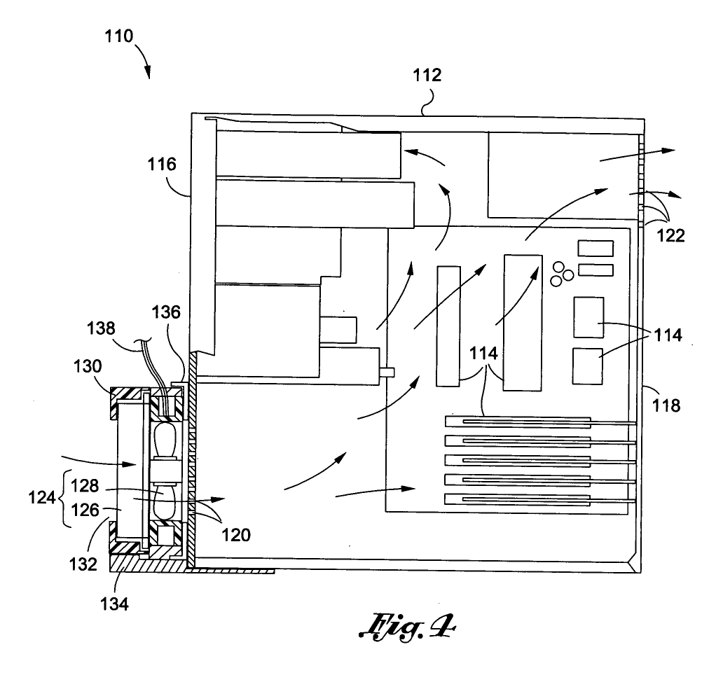

Therefore, an aspect of the present invention is directed toward maintaining the temperature of the computer components within their respective operable temperature ranges by inhibiting airborne particles from being introduced into the computer case. Referring now to the drawings, wherein the showings are for purposes of illustrating a preferred embodiment of the present invention only, and not for purposes of limiting the same, FIGS. 1-3 depict a computer case 10 constructed in accordance with the present invention. The computer case 10 includes an enclosure 12 for housing the computer components 14. A computer case 10 may include a personal computer, such as a desktop, tower, and laptop computer. The computer case 10 may also include a server or other computer equipment known by those skilled in the art. The enclosure 12 includes a forward face 16 and a rearward face 18. An inlet opening 20 is formed on the forward face 16 and an outlet opening 22 is formed on the rearward face 18. The inlet opening 20 is configured to allow ambient air to enter the enclosure 12 through the inlet opening 20. As used herein, ambient air is a general term that refers to the fluid immediately surrounding the outside of the computer case 10. The outlet opening 22 is configured to allow air within the enclosure 12 to exit through the outlet opening 22 at a first flow rate. The phrase air within the enclosure 12 generally refers to the fluid immediately enveloping the inside of the enclosure 12. In this manner, air flows across the computer enclosure 12 from the inlet opening 20 to the outlet opening 22, as best illustrated in FIGS. 1 and 3. Therefore, the enclosure 12 is configured to direct airflow through the enclosure 12 in a manner similar to many existing computer cases (e.g., from the forward face 16 to the rearward face 18). Consequently, the physical architecture and component layout commonly employed in most existing computer cases may be used in connection with the present invention.

In the embodiment shown in FIGS. 1-3, the inlet and outlet openings 20, 22 include a plurality of apertures formed in the forward and rearward faces 16, 18, respectively. However, it is understood that the inlet and/or outlet openings 20, 22 may be formed from a single aperture. Furthermore, the size and shape of the inlet and outlet openings 20, 22 may be varied without departing from the spirit and scope of the present invention. For instance, it may be desirable to form the inlet and/or outlet openings 20, 22 out of a series of slots.

The computer case 10 also includes an inlet assembly 24. The inlet assembly 24 is comprised of an air filter 26 and a fan 28. The air filter 26 and fan 28 are in fluid communication with the inlet opening 20. In this regard, fluid may pass between the fan 28 and the inlet opening 20. Likewise, fluid may pass between the filter 26 and the inlet opening. It is understood that intermediate channels may be employed without departing from the spirit and scope of the present invention. The fan 28 is configured to direct air through the filter 26 and into the inlet opening 20. The fan 28 directs air into the enclosure 12 at a second flow rate. The second flow rate is greater than the first flow rate, resulting in a positive air pressure within the enclosure 12. In other words, more air is being directed into the enclosure 12 through the inlet opening 20 than is exiting the enclosure 12 through the outlet opening 22.

In addition to the inlet and outlet openings 20, 22, the enclosure 12 likely includes a number of small crevices or openings through which air may pass. Such openings are commonly found near disk drives and other access points on the enclosure 12 but may be located anywhere on the enclosure 12. The positive air pressure created by the difference between the first and second flow rates forces air within the enclosure 12 to pass through the small openings, as shown in FIG. 1. Forcing air from the inside of the enclosure 12 to outside of the enclosure 12 through the small openings prevents ambient air from entering the enclosure 12 through such openings. Consequently, air particles in the ambient air are inhibited from entering the enclosure 12 through the small openings.

In many prior art computer cases, the flow rate of air entering the case is smaller than the flow rate of air exiting the case. This results in a negative air pressure, which draws unfiltered ambient air and airborne particles into the enclosure through the small openings and crevices in the case. As such, airborne particles commonly enter prior art computer cases through the small openings. The present invention may be distinguished from such prior art cases because of the positive air pressure created within the enclosure 12.

According to another aspect of the present invention, there is provided an air filter 26 in fluid communication with the inlet opening 20. To this end, air entering the computer enclosure 12 through the inlet opening 20 passes through the filter 26. Consequently, particles are removed from the air before the air travels across the computer components 14. Thus, fewer particles land on the computer components 14, resulting in a smoother, less turbulent airflow which provides more efficient heat transfer from the components 14 to the passing air. One embodiment of the invention includes an air filter 26 having a surface area that is greater than the inlet opening 20. In this regard, the air filter 26 covers the inlet opening 20 to prevent ambient air from entering the enclosure 12 through the inlet opening 20 without passing through the filter 26.

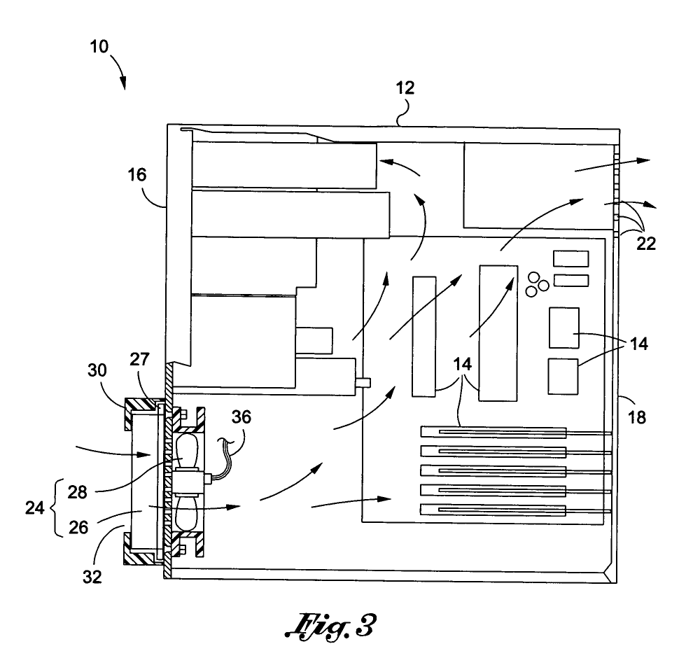

One particular implementation of the filter 26 includes a seal 27, as best illustrated in FIG. 2. The seal 27 fluidly seals the air filter 26 to the inlet opening 20. In this manner, the seal 27 inhibits air from entering the enclosure 12 without passing through both the filter 26 and the inlet opening 20.

It is contemplated that various types of filters 26 may be used. In one embodiment, an oil based cotton filter 26 is used. An example of an oil based cotton filter 26 is an automotive filter sold by K&N Engineering, Inc., (referred to herein as the “K&N filter”) having an office in Riverside, Calif. The K&N filter 26 is highly-efficient and long-lasting. Although the filter 26 sold by K&N Engineering, Inc., is marketed as an automotive filter 26, it may be used in connection with the computer case 10. The K&N filter 26 is washable and reusable, which decreases the maintenance cost and increases the longevity of use. A user is not required to buy a new filter 26 when the filter 26 gets dirty. Rather, an existing filter 26 can be cleaned and reused. Although the K&N filter 26 is one particular example of a filter 26 which may be used, other filters 26 known by those skilled in the art may additionally be used without departing from the spirit and scope of the present invention. For instance, a high efficiency particulate air (HEPA) filter 26 may be used in connection with the computer case 10.

The filter 26 may be disposed outside of the enclosure 12, as shown in FIGS. 1-3. Therefore, one embodiment includes a computer case 10 having a filter access door 30 connected to the forward face 16 to enable access to the filter 26. The embodiment illustrated in FIGS. 1-2 includes a filter access door 30 that is pivotally connected to the forward face 16. The door 30 is configured to receive the filter 26 and pivot to a closed position. In the closed position, the filter 30 is in fluid communication with inlet opening 20. The filter access door 30 includes an opening 32 through which ambient air may be drawn into the filter 26. The computer case 10 may further include a lock 34 to secure the door 30 in the closed position.

Air is directed into the filter 26 by a fan 28. It is contemplated that fans 28 being capable of generating various volumes of airflow may be used. The airflow volume generated by the fan 28 may depend on the size of the outlet opening 22. For instance, a larger outlet opening 22 will require more airflow in order to maintain a positive air pressure within the enclosure 12. The outlet opening 22 may be configured to have a variable size. For instance, the computer case 10 may include a slidable door which slides to open or close the apertures defining the outlet opening 22. As such, one embodiment includes a fan 28 having multiple settings, wherein each setting corresponds to a different flow rate corresponding to the size of the outlet opening 22. However, in another embodiment, the fan 28 is configured to direct air into the enclosure at a single flow rate. For instance, the fan 28 may be configured to direct approximately 15-20 cubic feet of air per minute through the inlet opening 20. However, other flow rates known by those skilled in the art can also be used.

In the embodiment depicted in FIGS. 1-3, the air filter 26 is disposed upstream of the inlet opening 20 and the fan 28 is disposed downstream of the inlet opening 20. However, it is understood that in another embodiment, the fan 28 is disposed upstream of the inlet opening 20 and the air filter 26 is disposed downstream of the inlet opening 20. In another implementation of the invention, the air filter 26 and fan 28 may be disposed on the same side of the inlet opening 20. For instance, the air filter 26 and fan 28 may both be upstream of the inlet opening 20. Alternatively, both the air filter 26 and fan 28 may be downstream of the inlet opening 20.

In the embodiment depicted in FIG. 3, the fan 28 is disposed downstream of the inlet opening 20 within the computer enclosure 12. It is understood that the fan 28 may be positioned adjacent to the outlet opening 22, while the filter 26 is positioned adjacent to the inlet opening 20.

As shown in FIG. 3, the fan 28 includes a power chord 36 that leads to a power source. In one embodiment, the fan 28 receives power from the computer power source. In another embodiment, the fan 28 includes an internal power source, such as a battery. In embodiments the fan 28 is disposed on the outside of the computer enclosure 12, in which case, the power chord 36 may connect to an external power source, such as a power outlet.

As mentioned above, the computer case 10 may be configured to create airflow from the forward face 16 to the rearward face 18. This may be desirable to mitigate exhausted air from blowing onto the computer user. However, it is understood that the computer case may be configured to create airflow from the rearward face 18 to the forward face 16, without departing from the spirit and scope of the present invention. In that case, the rearward face 18 may include an inlet opening 20 and the forward face 16 may include the outlet opening 22.

The foregoing describes a computer case 10 that may be configured to inhibit the introduction of airborne particles into the enclosure 12. However, many existing computer cases do not sufficiently inhibit airborne particles from entering. Therefore, according to another aspect of the present invention, and referring now to FIG. 4, there is provided a modular computer airflow generator 110 configured to inhibit the introduction of airborne particles into an existing computer enclosure 112. Many existing computer enclosures 112 include an inlet opening 120 on a forward face 116 and an outlet opening 122 on a rearward face 118. In this manner, air flows across the computer components 114 from the forward face 116 to the rearward face 118. The modular computer airflow generator 110 may be placed in fluid communication with the inlet opening 120 to provide enhanced airflow through the existing enclosure 112, while mitigating the introduction of airborne particles into the enclosure 112. As such, air may pass between the modular computer airflow generator 110 and the inlet opening 120. Therefore, the modular computer airflow generator 110 is configured to operate without disturbing the natural air flow path of the existing computer enclosure 112 (e.g., from the forward face 116 to the rearward face 118). In other words, the airflow generator 110 may adapt to the existing airflow design of the computer enclosure 112, thereby mitigating turbulent airflow over the computer components 114.

In one embodiment, the modular computer airflow generator 110 includes an inlet assembly 124 connected to a base 134. The inlet assembly 124 includes an air filter 126 and a fan 128. The fan 128 directs air through the filter 126 and into the inlet opening 120 at a second flow rate. The existing computer enclosure 112 includes at least one outlet opening 122 configured to allow air within the enclosure 112 to exit through the outlet opening 122 at a first flow rate, where the second flow rate is greater than the first flow rate. The airflow generator 110 further includes a seal 136 connected to the base 134. The seal 134 is positionable in contact with the computer enclosure 112 about the inlet opening 120 to fluidly seal the inlet assembly 124 to the computer enclosure 112. The seal 134 inhibits ambient air from entering the enclosure 112 without first passing through the filter 126.

As a result of the second flow rate being greater than the first flow rate, the airflow generator 110 creates a positive air pressure within the computer enclosure 112. As discussed in more detail above, the positive air pressure inhibits the introduction of airborne particles into the computer enclosure 112 through small openings formed on the computer enclosure 112. Furthermore, the various embodiments of fans 28 and filters 26 discussed above in relation to the computer case 10 also applies to the fan 128 and filter 126 of the modular computer airflow generator 110. However, with regard to the power of the fan 128 of the modular computer airflow generator 110, it may be beneficial to receive power independent from the computer. Therefore, the fan 128 may include a power chord 138, as illustrated in FIG. 4, which connects to an external power source. In addition, the fan 128 may include an internal power source, such as a battery, thereby allowing the modular computer airflow generator 110 to operate independent of an external power source.

It is contemplated that the inlet assembly 124 is positionable in fluid communication with and adjacent to the inlet opening 120. In this regard, a user may position the base 134 to place the inlet assembly 124 in fluid communication with the inlet opening 120. The position of the inlet assembly 124 may be adjusted relative to the base 134 to accommodate existing computer enclosures 112 having inlet openings 120 at different locations.

In one embodiment, the base 134 is placed under the computer enclosure 112, as shown in FIG. 4. As illustrated, the inlet assembly 124 is in front of, and in fluid communication with the inlet opening 120 when the base 134 is positioned under the computer enclosure 112. However, other embodiments of the invention include a base 134 that is not required to be placed under the computer enclosure 112.

According to an aspect of the invention, the modular airflow generator 110 may be used on different computer enclosures 112. If the user owns multiple computers, the modular airflow generator 110 may be used in connection with one computer enclosure 112, and then subsequently used in connection with another computer enclosure 112.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combinations described herein. Thus, the scope of the claims is not to be limited by the illustrated embodiments.

What is claimed is:

1. A computer case configured to inhibit the introduction of airborne particles into the computer case, the computer case comprising:
an enclosure for housing computer components, the enclosure having:
a forward face and a rearward face;
an inlet opening formed on the forward face, the inlet opening being configured to allow ambient air to enter the enclosure through the inlet opening; and
at least one outlet opening formed on the rearward face, the at least one outlet opening being configured to allow air within the enclosure to exit through the at least one outlet opening at a first flow rate, the inlet opening and the at least one outlet opening being in fluid communication to define airflow from the forward face to the rearward face within the enclosure; and
an inlet assembly in fluid communication with the inlet opening, the inlet assembly comprising:
an air filter; and
a fan configured to direct air through the filter and into the inlet opening at a second flow rate, the second flow rate being greater than the first flow rate.

2. The computer case as recited in claim 1, wherein the air filter is upstream of the fan.

3. The computer case as recited in claim 1, wherein the air filter is upstream of the inlet opening.

4. The computer case as recited in claim 1, wherein the fan is downstream of the inlet opening.

5. The computer case as recited in claim 4, wherein the air filter is upstream of the inlet opening.

6. The computer case as recited in claim 1 further comprises a filter access door pivotally connected to the forward face, the filter access door is configured to receive the air filter.

7. The computer case as recited in claim 1, wherein the air filter is a reusable filter.

8. The computer case as recited in claim 7, wherein the air filter is an oil based cotton filter.

9. The computer case as recited in claim 8, wherein the oil based cotton filter is upstream from the fan.

10. The computer case as recited in claim 1, wherein the air filter is a HEPA filter.

11. The computer case as recited in claim 1, wherein the fan directs 15-20 cubic feet of air per minute through the inlet opening.

12. The computer case as recited in claim 1, wherein the air filter includes a seal to fluidly seal the air filter to the inlet opening.

13. A modular computer airflow generator configured to inhibit the introduction of airborne particles into a computer enclosure, the computer enclosure having inlet and outlet openings, the outlet opening being configured to allow air to exit the computer enclosure through the outlet opening at a first flow rate, the modular computer airflow generator comprising:
a base;
an inlet assembly connected to the base and positionable in fluid communication with the inlet opening, the inlet assembly comprising:
an air filter; and
a fan configured to direct air through the filter and into the inlet opening at a second flow rate, the second flow rate being greater than the first flow rate; and
a seal connected to the base, the seal being positionable in contact with the computer enclosure about the inlet opening to fluidly seal the inlet assembly to the computer enclosure.

14. The modular computer airflow generator as recited in claim 13, wherein the inlet assembly is positionable upstream of the inlet opening.

15. The modular computer airflow generator as recited in claim 13, wherein the air filter is upstream of the fan.

16. The modular computer airflow generator as recited in claim 13 further comprises a filter access door pivotally connected to the base, the filter access door is configured to receive the air filter.

17. The modular computer airflow generator as recited in claim 13 wherein the air filter is a reusable filter.

18. The modular computer airflow generator as recited in claim 17 wherein the air filter is an oil based cotton filter.

19. The modular computer airflow generator as recited in claim 13 wherein the air filter is a HEPA filter.

20. The modular computer airflow generator as recited in claim 13 wherein the fan directs 15-20 cubic feet of air per minute through the inlet opening.
